(19) United States
(12) Patent Application Publication
(10) Pub. No.: US 2025/0208948 A1
(43) Pub. Date: Jun. 26, 2025

(54) DATA CORRUPTION INDICATION

(71) Applicant: Micron Technology, Inc., Boise, ID (US)

(72) Inventors: Nicola Del Gatto, Cassina de’ Pecchi (IT); Marco Sforzin, Cernusco Sul Naviglio (IT); Massimiliano Turconi, Gorgonzola (IT); Antonino Caprì, Bergamo (IT); Angelo Alberto Rovelli, Agrate Brianza (IT)

(21) Appl. No.: 18/973,325

(22) Filed: Dec. 9, 2024

Related U.S. Application Data
(60) Provisional application No. 63/613,892, filed on Dec. 22, 2023.

(51) Int. Cl. G06F 11/10; G06F 11/08

(52) U.S. Cl. CPC G06F 11/1004; G06F 11/085

(57) ABSTRACT

Apparatuses, systems, and methods for indicating data corruption are described. An example method can include receiving a write command to write user data to one or more memory units of a number of memory units. The method can further include generating a number of first bits that are invalid as error correction information or error detection information for the user data responsive to the user data being determined to be corrupted. The method can further include writing the user data to a first portion of the number of memory units and writing, along with the user data and instead of a number of second bits corresponding to the error correction information or the error detection information, the number of first bits to a second portion of the number of memory units.

### PRIORITY INFORMATION

This application claims the benefit of U.S. Provisional Application No. 63/613,892 filed on Dec. 22, 2023, the contents of which are incorporated herein by reference.

### TECHNICAL FIELD

The present disclosure relates generally to semiconductor memory and methods, and more particularly, to apparatuses, systems, and methods related to indicating data corruption.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 is a block diagram of a computing system including a memory controller in accordance with a number of embodiments of the present disclosure.

FIG. 2 is a block diagram of a memory controller having a data corruption component as well as a redundant array of independent disks (RAID) encoder/decoder in accordance with a number of embodiments of the present disclosure.

FIG. 3 is a block diagram of memory dice corresponding to a data protection channel in accordance with a number of embodiments of the present disclosure.

FIG. 4 illustrates a locked-RAID process for a data protection channel in accordance with a number of embodiments of the present disclosure.

FIG. 5 is a flow diagram of a method for indicating data corruption in accordance with a number of embodiments of the present disclosure.

### DETAILED DESCRIPTION

Systems, apparatuses, and methods related to indicating data corruption are described. Data protection schemes are often an important aspect of RAS (Reliability, Availability, and Serviceability) associated with memory systems. In such schemes, error correction and detection information can be generated based on data received from a host (alternatively referred to as “host data” or “user data”) and stored in storage devices along with the host data. In some approaches, the error correction and detection information can be later used to perform error detection and/or correction operations on the host data when read from the storage devices.

If error detection and/or correction operations performed on host data results in residual errors that were uncorrectable/uncorrected, this can be further reported to a host as the host data being “corrupted”. As used herein, the term “corruption”, “data corruption” or the similar refers to one or more bit errors on data (e.g., user data) that were uncorrectable/uncorrected, which necessitates reporting to a host of the uncorrectable bits. Often, the corruption can be indicated by a poison bit that can be set to indicate the corruption. In some approaches, this poison bit can be written to the storage devices along with the host data associated thereto so as to indicate the corruption on the host data when the poison bit read from the storage devices along with the host data. However, the memory space of storage devices can be often limited in that it is desired to reduce an amount (e.g., a quantity) of bits that would be stored in the storage devices along with the host data.

Embodiments are directed to indicating data corruption without having to have a dedicated bit (e.g., poison bit) to indicate such as to eliminate a need for further storing the dedicated bit in a memory. In a number of embodiments, for example, a functionality of the poison bit can be carried by changing contents (e.g., binary values) of the other data (data supplemental to the user data, such as error correction information, error detection information, etc.) that are anyhow to be stored in the memory. Whether user data is corrupted can be indicated by either looking at the contents themselves (e.g., whether a bit pattern of the contents match to a particular bit pattern) or based on error correction/detection operations that are designed to fail when performed using the changed contents. The failed error correction/detection operations (e.g., performed on the user data read from the memory) further triggers indication and report of the data corruption of the user data. Accordingly, while the functionality of a poison bit is preserved, a memory space spared from not having a dedicated poison bit can allow the other data (e.g., error correction information, error detection information, etc.) to be of a greater quantity of bits, which can strengthen functionality of the other data.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected. It is to be understood that data can be transferred, read, transmitted, received, or exchanged by electronic signals (e.g., current, voltage, etc.).

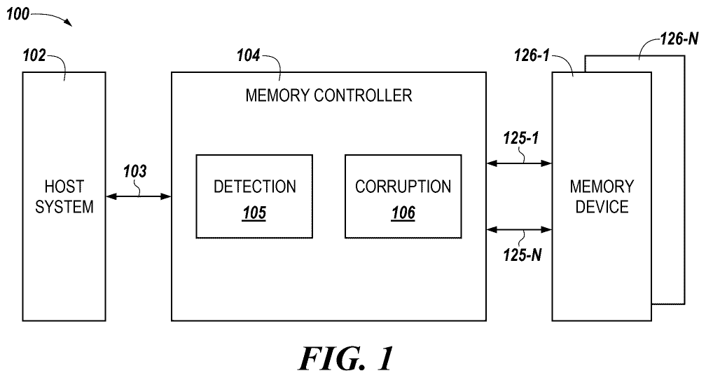

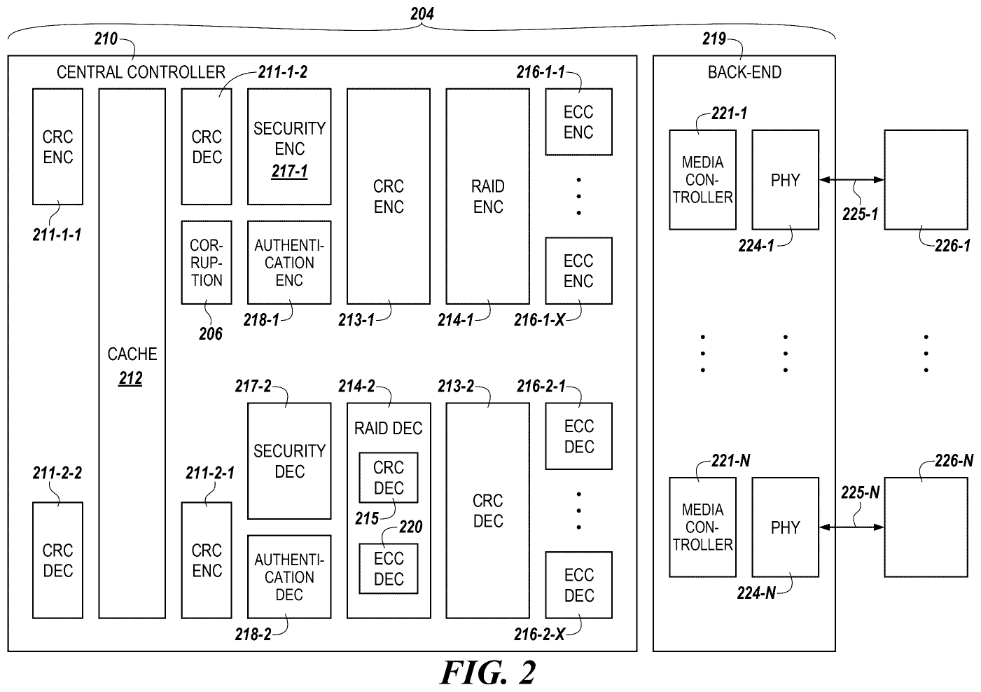

The figures herein follow a numbering convention in which the first digit or digits correspond to the drawing figure number and the remaining digits identify an element or component in the drawing. Similar elements or components between different figures may be identified by the use of similar digits. For example, 110 may reference element “10” in FIG. 1, and a similar element may be referenced as 210 in FIG. 2. Analogous elements within a Figure may be referenced with a hyphen and extra numeral or letter. See, for example, elements 102-1, 102-2, 102-M in FIG. 1. Such analogous elements may be generally referenced without the hyphen and extra numeral or letter. For example, elements 102-1, 102-2, 102-M may be collectively referenced as elements 102. As used herein, the designators “M” and “N”, particularly with respect to reference numerals in the drawings, indicates that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram in the form of a computing system 100 including a host 102, a memory controller 104, and memory devices 126-1, . . . , 126-N in accordance with a number of embodiments of the present disclosure. As used herein, a host system 102, a memory controller 104, and/or memory devices 126-1, . . . , 126-N might also be separately considered an “apparatus.”

The host 102 can include host memory and a central processing unit (not illustrated). The host 102 can be a host system such as a personal laptop computer, a desktop computer, a digital camera, a smart phone, a memory card reader, and/or internet-of-thing enabled device, among various other types of hosts, and can include a memory access device (e.g., a processor and/or processing device). One of ordinary skill in the art will appreciate that “a processor” can intend one or more processors, such as a parallel processing system, a number of coprocessors, etc.

The host 102 can include a system motherboard and/or backplane and can include a number of processing resources (e.g., one or more processors, microprocessors, or some other type of controlling circuitry). The system 100 can include separate integrated circuits or the host 102, the memory controller 104, and the memory devices 126 can be on the same integrated circuit. The system 100 can be, for instance, a server system and/or a high-performance computing (HPC) system and/or a portion thereof.

As illustrated in FIG. 1, a host 102 can be coupled to the memory controller 104 via an interface 103. The interface 103 can be any type of communication path, bus, or the like that allows for information to be transferred between the host 102 and the memory controller 104. Non-limiting examples of interfaces can include a peripheral component interconnect (PCI) interface, a peripheral component interconnect express (PCIe) interface, a serial advanced technology attachment (SATA) interface, and/or a miniature serial advanced technology attachment (mSATA) interface, among others. However, in at least one embodiment, the interface 103 is a PCIe 5.0 interface that is compliant with the compute express link (CXL) protocol standard. Accordingly, in some embodiments, the interface 103 can include a flexible bus interconnect and use CXL protocol layers including CXL.io and CXL.mem and can support transfer speeds of at least 32 gigatransfers per second.

The memory controller 104 can control performance of a memory operation for an access command received from the host 102. The memory operation can be a memory operation to read data (in response to a read request from the host) from or an operation to write data (in response to a write request from the host) to one or more memory devices 126. As further illustrated in described in connection with FIG. 2, the memory controller 104 can further include media controllers (e.g., the media controllers 221 illustrated in FIG. 2) each configured to control performance of a memory operation directed to a corresponding channel and/or memory device 126.

In some embodiments, the memory controller 104 can be a compute express link (CXL) compliant memory controller. The host interface (e.g., the front end portion of the memory controller 104) can be managed with CXL protocols and be coupled to the host 102 via an interface configured for a peripheral component interconnect express (PCIe) protocol. CXL is a high-speed central processing unit (CPU)-to-device and CPU-to-memory interconnect designed to accelerate next-generation data center performance. CXL technology maintains memory coherency between the CPU memory space and memory on attached devices, which allows resource sharing for higher performance, reduced software stack complexity, and lower overall system cost. CXL is designed to be an industry open standard interface for high-speed communications, as accelerators are increasingly used to complement CPUs in support of emerging applications such as artificial intelligence and machine learning. CXL technology is built on the PCIe infrastructure, leveraging PCIe physical and electrical interfaces to provide advanced protocol in areas such as input/output (I/O) protocol, memory protocol (e.g., initially allowing a host to share memory with an accelerator), and coherency interface.

The memory controller 104 can be coupled to the memory devices 126 via channels 125. The channels 125 can include various types data buses, such as a eight-pin data bus and a one-pin data mask inversion (DMI) bus, among other possible buses, although embodiments are not so limited. In some embodiments, the channels 125 can be part of a physical (PHY) layer. As used herein, the term “PHY layer” generally refers to the physical layer in the Open Systems Interconnection (OSI) model of a computing system. The PHY layer may be the first (e.g., lowest) layer of the OSI model and can be used transfer data over a physical data transmission medium.

The memory device(s) 126 can provide main memory for the computing system 100 or could be used as additional memory or storage throughout the computing system 100. The memory devices 126 can be various/different types of memory devices. For instance, the memory device can include RAM, ROM, DRAM, SDRAM, PCRAM, RRAM, and flash memory, among others. In embodiments in which the memory device 126 includes persistent or non-volatile memory, the memory device 126 can be flash memory devices such as NAND or NOR flash memory devices. Embodiments are not so limited, however, and the memory device 126 can include other non-volatile memory devices such as non-volatile random-access memory devices (e.g., non-volatile RAM (NVRAM), ReRAM, ferroelectric RAM (FeRAM), MRAM, PCRAM), “emerging” memory devices such as a ferroelectric RAM device that includes ferroelectric capacitors that can exhibit hysteresis characteristics, a memory device with resistive, phase-change, or similar memory cells, etc., or combinations thereof.

As an example, a FeRAM device can include ferroelectric capacitors and can perform bit storage based on an amount of voltage or charge applied thereto. In such examples, relatively small and relatively large voltages allow the ferroelectric RAM device to exhibit characteristics similar to normal dielectric materials (e.g., dielectric materials that have a relatively high dielectric constant) but at various voltages between such relatively small and large voltages the ferroelectric RAM device can exhibit a polarization reversal that yields non-linear dielectric behavior.

As another example, an array of non-volatile memory cells, such as resistive, phase-change, or similar memory cells, can perform bit storage based on a change of bulk resistance, in conjunction with a stackable cross-gridded data access array. Additionally, in contrast to many flash-based memories, the non-volatile memory can perform a write in-place operation, where a non-volatile memory cell can be programmed without the non-volatile memory cell being previously erased.

One example of the memory devices 126 is dynamic random access memory (DRAM) operated according to a protocol such as low-power double data rate (LPDDRx), which may be referred to herein as LPDDRx DRAM devices, LPDDRx memory, etc. The “x” in LPDDRx refers to any of a number of generations of the protocol (e.g., LPDDR5). In at least one embodiment, at least one of the memory devices 126-1 is operated as an LPDDRx DRAM device with low-power features enabled and at least one of the memory devices 126-N is operated an LPDDRx DRAM device with at least one low-power feature disabled. In some embodiments, although the memory devices 126 are LPDDRx memory devices, the memory devices 126 do not include circuitry configured to provide low-power functionality for the memory devices 126 such as a dynamic voltage frequency scaling core (DVFSC), a sub-threshold current reduce circuit (SCRC), or other low-power functionality providing circuitry. Providing the LPDDRx memory devices 126 without such circuitry can advantageously reduce the cost, size, and/or complexity of the LPDDRx memory devices 126. By way of example, an LPDDRx memory device 126 with reduced low-power functionality providing circuitry can be used for applications other than mobile applications (e.g., if the memory is not intended to be used in a mobile application, some or all low-power functionality may be sacrificed for a reduction in the cost of producing the memory).

The memory controller 104 can include an error detection component 105 (shown as “DETECTION” in FIG. 1). The error detection component 105 can detect one or more bit errors on user data received from the host 102. Although not shown in FIG. 1 and so as to not obfuscate the drawings, the error detection component 105 can include various circuitry to facilitate performance of operations described herein. For example, the error detection component 105 can include an error detection encoder that can generate error detection information based on user data and an error detection decoder that can perform an error detection operation on the user data by decoding the user data using the error detection information, which determines if the user data has one or more bit errors. In some embodiments, the error detection information that can be generated at error detection component 105 can be cyclic redundancy code (CRC) data.

The error detection component 105 can operate to examine user data on a write path. For example, the user data can be examined for any bit errors prior to being written to memory devices 126. Error detection encoder/decoder of error detection component 105 can be respectively located in various locations on a write path of the controller 104 to allow error detection operations performed on user data at any point on a write path.

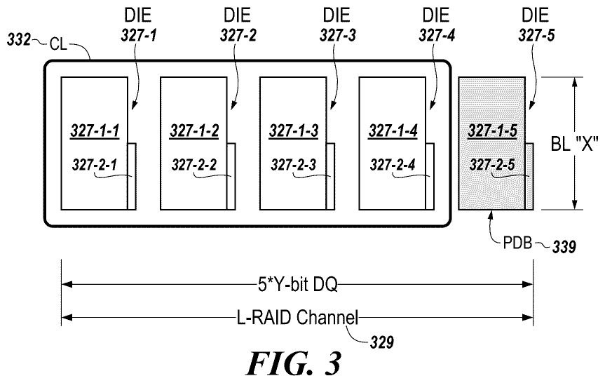

If user data is found to have one or more bit errors on a write path or the host 102 request user data to be marked as such, the user data can be determined/marked to be “corrupted”. The “corrupted” user data can be input (e.g., transferred) to a data corruption component 106 (shown as “CORRUPTION” in FIG. 1), which can generate supplemental data (alternatively referred to as “extra data” or “extra bits” that are to be written to memory devices 126 along with user data) whose bit pattern is designed to carry functionalities of a poison bit, which can be used to indicate whether data (e.g., user data) is corrupted or not. As used herein, the term “supplemental data” can refer to data that do not correspond to user data, but are supplemental to the user data and designed for providing particular functionalities, such as error correction and/or detection capabilities. As further illustrated in FIG. 3, memory dice of memory devices 126 can have dedicated locations for storing supplemental data, such as second portions 327-2-1, . . . , 328-2-5 of memory dice 327-1, . . . , 327-4 illustrated in FIG. 3.

Further, as used herein, supplemental data (e.g., generated at the data corruption component 106) to cause failure of error correction/detection operations can be referred to as “false data” or “false information”. In one example, the corruption can be indicated by determining whether a bit pattern of the false information matches to a particular pattern or not, which can be further determined at the data corruption component 106 when the false information is read (along with the user data) from memory devices 126. In another example, a bit pattern of the false information can be designed in a manner that guarantees error correction and/or detection operations performed on a read path of the data (e.g., user data) to be failed, which can further cause memory controller 104 to report data corruption of the user data to the host 102. In a different example, the corruption can be indicated when the above two conditions are met (e.g., the bit pattern of the false information that failed the error correction and/or detection operations matches to the particular pattern). In any of these examples, false information can be generated with a bit pattern that is invalid (e.g., not equal to) as error correction information, error detection information, etc. that would have been generated at the other components of the controller 104 (e.g., CRC encoder 213-1, ECC encoders 216-1-1, . . . , 216-1-X, etc. illustrated in FIG. 2).

If user data is determined not to have one or more bit errors on a write path, the user data may not be input to data corruption component 106. Instead, supplemental data can be generated via other components of the controller 104 that actually generate error detection information, error correction information (e.g., parity data), data recovery information (RAID parity data), etc. that can be further used to perform error correction operations, error detection operations, data recovery operations (e.g., RAID operations), etc. on a read path of the data. Further details of this process are described in connection with FIG. 2.

FIG. 2 is a functional block diagram of a memory controller 204 having a data corruption component 206 as well as a RAID encoder and 214-1 and a RAID decoder 214-2 in accordance with a number of embodiments of the present disclosure. The memory controller 204 and the memory devices 226 illustrated in FIG. 2 are analogous to the memory controller 104 and the memory devices 126 illustrated in FIG. 1.

The central controller portion 210 includes a cache 212 to store data (e.g., user data), error detection information, error correction information, and/or metadata associated with performance of the memory operation. An example of the cache 212 is a thirty-two (32) way set-associative cache including multiple cache lines. While host read and write commands can be of a particular size (e.g., 64 bytes), the cache line size can be greater than the size. As used herein, the term “user data block” (UDB) can refer to data corresponding to a unit of host read and write access. In some embodiments, the cache line size can correspond to a size of 2 UDBs (with each UDB being a 64-byte chunk), such as 128 bytes.

Use of the cache 212 to store data associated with a read operation or a write operation can increase the speed and/or efficiency of accessing the data because the cache 212 can prefetch the data and store the data in multiple 64-byte blocks in the case of a cache miss. Instead of searching a separate memory device in the event of a cache miss, the data can be read from the cache 212. Less time and energy may be used accessing the prefetched data than would be used if the memory system has to search for the data before accessing the data.

These UDBs stored in each cache line (e.g., alternatively referred to as “UDBs corresponding to a cache line”) can be a data transfer unit of data paths between the cache 212 and the memory devices 226. For example, even though a host read/write command is a size of an UDB, such as 64 bytes, the UDBs corresponding to a cache line can be collectively transferred between the cache 212 and the memory devices 226 (e.g., through other encoder/decoder illustrated in FIG. 2) as a chunk. Therefore, the UDBs corresponding to a cache line can be collectively encrypted/decrypted at various encoder/decoders illustrated in FIG. 2 and located between the cache 212 and the memory devices 226. Therefore, UDBs corresponding to a cache line can correspond to a same RAID stripe as further described below.

The central controller portion 210 includes a front-end CRC (“FCRC”) encoder 211-1-1 and a FCRC decoder 211-1-2 with the cache located between the two. The FCRC encoder 211-1-1 can generate error detection information based on data (e.g., an UDB in “plain text” form) received as a part of a write command (e.g., received from the host 102 illustrated in FIG. 1) and before writing the data to the cache 212. The error detection information generated at the FCRC encoder 211-1 can be a check value, such as CRC data. Read and write commands of CXL memory systems can be a size of UDB, such as 64 bytes. Accordingly, the data received at the FCRC encoder 211-1 can correspond to an UDB. The FCRC decoder 211-1-2 can be configured to check any errors on an UDB stored in the cache 212 using error detection information (e.g., CRC data) generated at the FCRC encoder 211-1-1. Although FIG. 2 illustrates CRC encoder/decoder 211-1-1 and 211-1-2 in a manner that the cache 212 is located between the two, embodiments are not limited to particular locations, in which CRC encoder/decoder 211-1-1 and 211-1-2 can be placed.

A result of the check (e.g., error detection operation) performed at the FCRC decoder 211-1-2 can be used to determine a route of a write path associated with writing one or more UDBs to memory devices 226. For example, if the check indicates one or more bit errors on the UDBs, which further indicates the UDBs being corrupted, the write path of the UDBs can be routed via a data corruption component 206 and by bypassing one or more components, such as a security encoder 217-1, an authentication encoder 218-1, a CRC encoder 213-1, a RAID encoder 214-1, and/or ECC encoders 216-1-1, . . . , 216-1-X.

The data corruption component 206 can generate false information that can be written to memory devices 226 (along with one or more UDBs corresponding to a cache line) when the UDBs are determined to be corrupted. A bit pattern of the false information generated at the data corruption component 206 do not correspond to error correction and/or detection information that may be generated at ECC encoders 216-1-1, . . . , 216-1-X and CRC encoder 213-1 such that error correction and/or detection operations performed using the false information are designed to fail. Further, in some embodiments, the bit pattern of the false information can be of a particular bit pattern (in addition to being designed to fail the error correction and/or detection operations). Therefore, in this example, the corruption can be indicated when the bit pattern read from the memory devices 226 fails the error correction and/or detection operations and matches to the particular pattern. In some embodiments, the data corruption component 206 can further generate a bit pattern (e.g., predetermined) that would be written to memory devices 226 in lieu of the UDBs. In this example, the generated bit pattern can be written to memory devices 226 along with false information and without writing UDBs to the memory devices 226.

The central controller portion 210 further includes a security encoder 217-1 (e.g., paired with a security decoder 217-2) to encrypt data (e.g., UDBs corresponding to a cache line) before transferring the data to a CRC encoder 213-1 (to write the data to the memory devices 226). Although embodiments are not so limited, the pair of security encoder/decoder 217 can operate using an AES encryption/decryption (e.g., algorithm). Unencrypted data (e.g., plain text) can be converted to cypher text via encryption by the security encoder 217-1. The central controller portion 210 further includes an authenticity/integrity check encoder 218-1 to generate authentication data based on data received from the cache 212. Although embodiments are not so limited, the authentication data generated at the authenticity/integrity check encoder 218-1 can be MAC, such as KECCAK MAC (KMAC) (e.g., SHA-3-256 MAC).

In some embodiments, the MAC generated at the authenticity/integrity check encoder 218-1 can be calculated based on trusted execution environment (TEE) data (alternatively referred to as “TEE flag”), Host Physical Address (HPA) (e.g., a memory address used/identified by the host 102 illustrated in FIG. 1 in association with host read/write transactions), a security key identifier (ID) that are associated with a physical address (of the memory devices 226) to be accessed for executing a host write command.

The security encoder 217-1 and the authenticity/integrity check encoder 218-1 can operate in parallel. For example, the data stored in the cache 212 and that are in plain text form can be input (e.g., transferred) to both the security encoder 217-1 and the authenticity/integrity check encoder 218-1. In some embodiments, a security key ID can be further input (along with the data in plain text form) to the security encoder 217-1. Further, in some embodiments, a security key ID, TEE flag, and an HPA associated with a host write command can be further input (along with the data in plain text form) to the authenticity/integrity check encoder 218-1.

The central controller portion 210 includes a CRC encoder 213-1 (e.g., paired with a CRC decoder 213-2) to generate error detection information (e.g., alternatively referred to as CRC media (CRCm)) based collectively on UDBs corresponding to a cache line received from the security encoder 217-1. The data transferred to the CRC encoder 213-1 from the security encoder 217-1 can be in cypher text form as the data were previously encrypted at the security encoder 217-1. The error detection information generated at the ECC encoder 213-1 can be a check value, such as CRC data. The CRC encoder 213-1 and CRC decoder 213-2 can operate on data having a size equal to or greater than a cache line size.

The central controller portion 210 includes RAID encoder 214-1 (e.g., paired with a RAID decoder 214-2) to generate and/or update RAID parity data (e.g., a PDB) based at least in part on data (e.g., one or more UDBs corresponding to a cache line) received from the CRC encoder 213-1. The data transferred to the RAID encoder 214-1 from the CRC encoder 213-1 can be in cypher text form as the data were encrypted at the security encoder 217-1.

The RAID encoder 214-1 can update the PDB to conform to new UDB received as part of a write command from the host. To update the PDB, an old UDB (that is to be replaced with the new UDB) and an old PDB (of a same stripe as the old UDB) can be read (e.g., transferred to the RAID encoder 214-1) and compared (e.g., XORed) with the new UDB, and a result of the comparison (e.g., the XOR operation) can be further compared (e.g., XORed) with an old PDB (that is to be updated) to result in a new (e.g., updated) PDB.

As shown in FIG. 2, the central controller portion 210 can include ECC encoders 216-1-1, . . . , 216-1-X. The data transferred to each ECC encoder 216-1 can be in cypher text form as the data were previously encrypted at the security encoder 217-1. Each ECC encoder 216-1 can be responsible for a respective region of the memory devices 226, such as a set of memory dice (e.g., the memory dice 327-1, . . . , 327-4 illustrated in FIG. 3), although embodiments are not so limited. For example, each ECC encoder 216-1 can operate based on input data (one or more UDBs) corresponding to a cache line.

Each ECC encoder 216-1 can be configured to generate ECC data (alternatively referred to as “error correction information”) based collectively on data (e.g., UDBs corresponding to a cache line) transferred from the RAID encoder 214-1. The ECC data can include parity data.

Each ECC encoder 216-1 can be paired with a respective one of ECC decoders 216-2-1, . . . , 216-2-X to operate in a collective manner and to be dedicated for each memory device 226 and/or each memory die of the memory devices 226. For example, an ECC encoder 216-1-1 that is responsible for one memory die of the memory device 226-1 can be grouped with an ECC decoder 216-2-1 that is also responsible for the memory die, which allows ECC data that were generated at the ECC encoder 216-1-1 to be later transferred to (e.g., stored in) the ECC decoder 216-2-1 for performing an error correction operation on data (e.g., a portion of MTB) stored in the memory die.

When one or more UDBs (corresponding to a cache line) are determined to be corrupted, one or more components of the central controller portion 210 can be bypassed on a write path associated with writing UDBs to memory devices 226. For example, the CRC encoder 213-1 and ECC encoders 216-1-1, . . . , 216-1-X can be bypassed such that UDBs are written to memory devices 226 without generating error correction information and/or error detection information that would have been generated at the CRC encoder 213-1 and ECC encoders 216-1-1, . . . , 216-1-X, respectively.

As shown in FIG. 2, the memory controller 204 can include a back end portion 219 coupled to the central controller portion 210. The back end portion 219 can include media controllers 221-1, . . . , 221-N. The back end portion 219 can include PHY memory interfaces 224-1, . . . , 224-N. Each physical interface 224 is configured to be coupled to a respective memory device 226.

The media controllers 221-1, . . . , 221-N can be used substantially simultaneously to drive the channels 225-1, . . . , 225-N simultaneously. In at least one embodiment, each of the media controllers 221 can receive a same command and address and drive the channels 225 substantially simultaneously. By using the same command and address, each of the media controllers 221 can utilize the channels 225 to perform the same memory operation on the same memory cells.

As used herein, the term “substantially” means that the characteristic need not be absolute, but is close enough so as to achieve the advantages of the characteristic. For example, “substantially simultaneously” is not limited to operations that are performed absolutely simultaneously and can include timings that are intended to be contemporaneous but due to manufacturing limitations may not be precisely simultaneously. For example, due to read/write delays that may be exhibited by various interfaces (e.g., LPDDR5 vs. PCIe), media controllers that are utilized “substantially simultaneously” may not start or finish at exactly the same time. For example, the memory controllers can be utilized such that they are writing data to the memory devices at the same time regardless of whether one of the media controllers commences or terminates prior to the other.

The channels 225 can include a number of separate data protection channels (alternatively referred to as RAS (Reliability, Availability, and Serviceability) channel), which can each comprise a number of memory devices (e.g., dice) 226 accessed together in association with a particular data protection scheme (e.g., RAID, LPCK, etc.). The data protection channels can include RAID (e.g., locked-RAID) channels. In a RAID process that is “locked”, all the subsets corresponding to a RAID stipe are collectively accessed together regardless of whether a corresponding RAID process is triggered or not. For example, the subsets can be collectively accessed together even in response to a mere host read request for accessing a portion (e.g., one) of the subsets, which makes a RAID process readily available without incurring an additional/separate access to the other subsets. As used herein, the term “RAID channel” refers to one or more channels (e.g., channels 125 and/or 225 illustrated in FIGS. 1 and 2, respectively) that are accessed together for RAID access. Alternatively speaking, a RAID channel can be an access unit for transfer of a single RAID stripe. For example, the channels 225 can be organized as a number of RAID channels with each RAID channel comprising a particular quantity of channels 225.

The PHY memory interfaces 224 can be an LPDDRx memory interface. In some embodiments, each of the PHY memory interfaces 224 can include data and DMI pins. For example, each PHY memory interface 224 can include forty data pins (DQ pins) and four DMI pins. The media controllers 221 can be configured to exchange user data (e.g., UDBs corresponding to a cache line) with a respective memory device 226 via the data pins. The media controllers 221 can be configured to exchange at least a portion of the other data (that are not user data) via the DMI pins as opposed to exchanging such information via the data pins. The “other” data that can be exchanged via the DMI pins can include error correction information (e.g., ECC data), error detection information, false information, and or metadata via the DMI pins as opposed to exchanging such information via the data pins. The DMI pins can serve multiple functions, such as data mask, data bus inversion, and parity for read operations by setting a mode register. The DMI bus uses a bidirectional signal. In some instances, each transferred byte of data has a corresponding signal sent via the DMI pins for selection of the data. In at least one embodiment, the data can be exchanged simultaneously with the error correction information and/or the error detection information. For example, 64 bytes of data (e.g., UDBs corresponding to a cache line) can be exchanged (transmitted or received) via the data pins while 64 bits of the extra bits are exchanged via the DMI pins. Such embodiments reduce what would otherwise be overhead on the data input/output (e.g., also referred to in the art as a “DQ”) bus for transferring error correction information, error detection information, and/or metadata.

The back end portion 219 can couple the PHY memory interfaces 224-1, . . . , 224-N to respective memory devices 226-1, . . . , 226-N. The memory devices 226 each include at least one array of memory cells. In some embodiments, the memory devices 226 can be different types of memory. The media controllers 221 can be configured to control at least two different types of memory. For example, the memory device 226-1 can be LPDDRx memory operated according to a first protocol and the memory device 226-N can be LPDDRx memory operated according to a second protocol different from the first protocol. In such an example, the first media controller 221-1 can be configured to control a first subset of the memory devices 226-1 according to the fist protocol and the second media controller 221-N can be configured to control a second subset of the memory devices 226-N according to the second protocol.

Data (one or more UDBs corresponding to a cache line) stored in the memory devices 226 can be transferred to the back end portion 219 to be ultimately transferred and written to the cache 212 and/or transferred to the host (e.g., the host 102 illustrated in FIG. 1). In some embodiments, the data are transferred in response to a read command to access a subset of the data (e.g., one UDB) and/or to synchronize the cache 212 and the memory devices 226 to clean up “dirty” data in the cache 212.

Along with the UDBs, other data can be transferred to the back end portion 219 as well. For example, the other data that are not UDBs can include supplemental data (either false information generated at the data corruption component 206 or CRC data and ECC data generated at the CRC encoder 213-1 and ECC encoders 216-1), and authentication data generated at the authenticity/integrity check encoder 218-1 that are associated with the UDBs as well as metadata and/or TEE data. As described herein, the UDBs transferred to the back end portion 219 can be in cypher text form.

Data (e.g., UDBs corresponding to a cache line) transferred to the back end portion 219 can be further transferred to the respective ECC decoders 216-2. At each ECC decoder 216-2, an error correction operation can be performed on the data to correct error(s) up to a particular quantity and/or detect errors beyond particular quantity without correcting those. In one example, each ECC decoder 216-2 can use the error correction information (e.g., ECC data) to correct a single error without detecting two or more errors, which is referred to as a single error correction (SEC) operation. In another example, each ECC decoder 216-2 can use the error correction information (e.g., ECC data) to either correct a single error or detect two errors (without correcting two errors), which is referred to as a single error correction and double error detection (SECDED) operation. In a different example, each ECC decoder 216-2 can use the error correction information to either correct two errors or detect three errors (without correcting three errors), which is referred to as a double error correction and triple error detection (DECTED) operation.

As described herein, each ECC decoder 216-2 can be responsible for a respective memory device 226 as the paired ECC encoder 216-1 is. the ECC decoder 216-2 (e.g., each ECC decoder 216-2) can be configured to perform an error correction operation on data (e.g., UDBs) transferred from a respective set of memory dice (that correspond to a cache line) using the ECC data. In some embodiments, pairs of ECC encoder/decoder 216 can be selectively enabled/disabled to transfer data between the memory devices 226 and the memory controller 204 without generating error correction information (e.g., ECC data) and/or performing an error correction operation using the pairs.

When the error correction operation (e.g., performed at the ECC decoder 216-2) is performed using false information generated at the data corruption component 206, the false information can cause the error correction operation to be failed (e.g., errors may not be corrected/detected). Accordingly, in this example, data (corresponding to the false information) that were input to the ECC decoders 216-2 are further input to the CRC decoder 213-2 without any bit errors being corrected at the ECC decoder 216-2.

Subsequent to error correction operations performed respectively at the ECC decoders 216-2, the UDBs corresponding to a cache line can be further transferred to the CRC decoder 213-2 along with at least the error detection information previously generated at the CRC encoder 213-1. At the CRC decoder 213-2, an error detection operation can be performed to detect any errors in the UDBs using the error detection information, such as CRC data.

The CRC decoder 213-2 can operate on data in conjunction with the RAID decoder 214-2 to provide check-and-recover correction. More specifically, the CRC decoder 213-2 can detect an error in data (e.g., received from the respective ECC decoder 216-2) and the RAID decoder 214-2 can recover the data in response. In at least one embodiment, the check-and-recover correction provided by the error detection circuitry 211 and the RAID decoder 214-2 is supplemental to the error correction provided by the ECC decoder 216-2. For example, if data (e.g., UDBs corresponding to a cache line) transferred from the memory devices 226 has an error correctable by the ECC decoder 216-2, it can do so without further data recovery (e.g., one or more RAID operations) by the RAID decoder 214-2. However, if an error persists that is not correctable by the ECC decoder 216-2, then the data may be recoverable by the RAID decoder 214-2. As another example, an error may escape detection by the ECC decoder 216-2, but be detected by the CRC decoder 213-2. In such an example, the underlying data may be recoverable by the RAID decoder 214-2.

When the error detection operation (e.g., performed at the CRC decoder 213-2) is performed using false information generated at the data corruption component 206, the false information can cause the error detection operation to indicate errors on data. Accordingly, in this example, this error detection operation performed using false information can further lead to a trigger of RAID process.

When the RAID process is triggered, the RAID operation performed on the UDB (e.g., corresponding to a cache line) can recover a subset of the UDB that was transferred from one (e.g., failed) memory die based on the other subsets of the UDB transferred from the other memory dice. Since all the subsets (of the UDB) is collectively input (e.g., transferred) to the CRC decoder (e.g., the CRC decoder 213-2 illustrated in FIG. 2) and collectively checked for one or more errors (alternatively referred to as “locked-RAID”), the CRC check performed at the CRC decoder may not indicate which subset has one or more errors. Therefore, the triggered RAID process involves a number of RAID operations that can be respectively and independently performed on each subset to correct the one subset that indeed has the errors. For example, considering an UDB is received from four memory dice (e.g., the memory dice 327-1, . . . , 327-4 illustrated in FIG. 3), four RAID operations can be performed (e.g., in parallel or in a particular sequence) independent and respectively on each subset (corresponding to each memory dice) of the UDBs.

The RAID decoder 214-2 can further include an ECC decoder 220, which can provide the same functionality as the ECC decoder 216-2. For example, the ECC decoder 220 can be configured to perform an error correction operation on data (e.g., UDBs corresponding to a cache line) transferred from the CRC decoder 213-2. The ECC decoder 220 can operate in conjunction with a RAID process to correct any residual errors on the UDBs. For example, bit errors caused from the RAID process, but are correctable using the respective ECC data can be corrected at the ECC decoder 220. On the other hand, if false information is used to perform an error correction operation at the ECC decoder 220, the false information can lead to failure of the error correction operation, which can further lead to UDBs being input to the CRC decoder 213-2 without any bit errors being corrected.

In some embodiments, the RAID decoder 214-2 can further include a CRC decoder 215 that provides the same functionality as the CRC decoder 213-2, but to perform an error detection operation (e.g., to CRC-check) on data (e.g., UDBs corresponding to a cache line) subsequent to the RAID operations and/or the error correction operations performed by the ECC decoder 220. Continuing with the above example, the CRC check can be performed using the CRC decoder within the RAID decoder 214-2 on results of the four RAID operations to determine which one of the RAID operations actually recovered the UDBs. If any one of the results is found to have no bit errors, the result can be further sent to the security decoder 217 and/or authentication decoder 218. On the other hand, if false information was previously input to the ECC decoder 220 and to the CRC decoder 215, this results in CRC decoder 216 indicating none (or at least more than one result) of the results of RAID operations as having one or more bit errors (which can be referred to as “failure” of error detection operations).

Accordingly, when this failure is indicated at the CRC decoder 215, the data (e.g., false information) that cause the failure can be further input to the corruption component to determine whether a bit pattern of the data matches a particular (e.g., predetermined) bit pattern that was assigned to the false information. If the match is determined, the memory controller 204 can notify the host (e.g., the host 102 illustrated in FIG. 1) of the corruption of UDBs.

The data (e.g., UDBs corresponding to a cache line) can be further transferred to the security decoder 217-2 and to the authenticity/integrity check decoder 218-2 (shown as “AUTHENTICATION DEC” 218-2 in FIG. 2) along with at least the authentication data previously generated at the authenticity/integrity check encoder 218-1. At the security decoder 217-2, the data can be decrypted (e.g., converted from the cypher text back to the plain text as originally received from the host). The security decoder 217-2 can use an AES decryption to decrypt the data.

At the authenticity/integrity check decoder 218-2, the data that were decrypted at the security decoder 217-2 can be authenticated (and/or checked for data integrity) using the authentication data (e.g., MAC data) that were previously generated at the authenticity/integrity check encoder 218-1. In some embodiments, the authenticity/integrity check decoder 218-2 can calculate MAC based on TEE data, HPA, and the security key ID associated with a physical address to be accessed for executing a host read command. The MAC that is calculated during the read operation can be compared to the MAC transferred from (a location corresponding to the physical address of) the memory devices 226. If the calculated MAC and transferred MAC match, the UDB is written to the cache 212 (and further transferred to the host if needed). If the calculated MAC and transferred MAC do not match, the host is notified of the mismatch (and/or the poison).

The data (e.g., UDBs corresponding to a cache line) authenticated (and/or checked for data integrity) at the authenticity/integrity check decoder 218-2 can be transferred and written to the cache 212. As described herein, host read and write commands of CXL memory systems can be a size of UDB, such as 64 bytes. For example, data can be requested by the host in a granularity of an UDB. In this example, even if data transferred from the memory devices 226 are multiple UDBs (corresponding to a cache line), data can be transferred from the cache 212 to the host in a granularity of an UDB. As illustrated in FIG. 2, the controller 204 can further include a pair of CRC encoder/decoder 211-2-1 and 211-2-2, which can check for any errors (e.g., using CRC data) on data stored in the cache. For example, at the FCRC decoder 211-2, data (e.g., an UDB requested by the host) can be checked (CRC-checked) for any errors using CRC data that were previously generated at the FCRC encoder 211-1. The data decrypted at the FCRC decoder 211-2 can be further transferred to the host (e.g., the host 102 illustrated in FIG. 1).

FIG. 3 is a block diagram of memory dice corresponding to a number of data protection channels (e.g., RAID channels) in accordance with a number of embodiments of the present disclosure. The diagram illustrates five memory dice 327-1, . . . , 327-5, which can collectively correspond to a RAID (e.g., locked-RAID) channel 329, while four memory dice 327-1, . . . , 327-4 of those correspond to a cache line 332.

Each memory die 327 can include separate portions having different types of data pins, such as DQ pins and DMI pins. For example, a first portion 327-1-1, 327-2-1, 327-3-1, 327-4-1, 327-5-1 of each memory die 327 can include DQ pins via which data can be transferred. Further, a second portion 327-1-2, 327-2-2, 327-3-2, 327-4-2, 327-5-2 of each memory die 327 can include DMI pins via which data can be transferred.

Data can be transferred to or from the memory die 327 over a predefined burst length, such as over X-bit burst length. Further, data can be transferred at a rate of Y bits to or from the respective first portion 327-1-1, 327-2- 1, 327-3-1, 327-4-1, 327-5-1 per beat and at a rate of Z bit(s) to or from the respective second portion 327-2. In one example, 16 bytes of data can be transferred to or from each first portion 327-1-1, 327-2-1, 327-3-1, 327-4-1, 327-5-1 over the 16-bit burst length at a rate of 8 bits per beat, while 8 bits of data can be transferred to or from each second portion 327-1-2, 327-2-2, 327-3-2, 327-4-2, 327-5-2 over the 16-bit burst length at a rate of 1 bit per beat.

Although embodiments are not so limited, two memory dice 327 can correspond to (e.g., a channel width) of the channel 125 and/or 225 illustrated in FIGS. 1 and 2, respectively. For example, memory dice 327-1 and 327-2 can correspond to one channel 125, 225; memory dice 327-3 and 327-4 can correspond to another channel 125, 225; and memory die 327-5 can correspond to (a half of) a different channel 125, 225. Accordingly, each channel 125, 225 can be 2*Y-bit wide (e.g., 16-bit wide).

The memory dice 327-1, . . . , 327-5 can correspond to a same memory rank of memory device (e.g., the memory devices 126 and/or 226 illustrated in FIGS. 1 and 2). As used herein, the term “memory ranks” generally refers to a plurality of memory chips (e.g., memory dice) that can be accessed simultaneously. Accordingly, memory dice 327-1, . . . , 327-5 can be accessed simultaneously (e.g., “substantially simultaneously” as defined herein).

The diagram shows four memory dice 327-1, . . . , 327-4 (of RAID channel 329) over which data corresponding to a cache line 332 can be stored. Although embodiments are not limited to a particular quantity of memory dice over which a single UDB can be stored, the cache line 332 can correspond to a single UDB such that this single UDB is stored over memory dice 327-1, . . . , 327-4. Further, although embodiments are not so limited, data corresponding to the cache line 332 can be stored in the respective first portions 327-1-1, 327-2-1, 327-3-1, 327-4-1 of the memory dice 327.

Further, supplemental data can be stored over the respective second portions 327-1-2, 327-2-2, 327-3-2, 327-4-2, 327-5-2 of the memory dice 327-1, . . . , 327-4, 327-5. In a particular example, each second portion 327-1-2, 327-2-2, 327-3-2, 327-4-2, 327-5-2 can be configured to store 5 bytes of supplemental data (1 byte for each memory die 327). The supplemental data (e.g., 40 bits of supplemental data) can include error detection data (e.g., 28 bits of CRC generated at the CRC encoder 213-1) and error correction data (e.g., 12 bits of ECC data).

As described herein, supplemental data can be filled with either error detection information (e.g., 28 bits of CRC generated at the CRC encoder 213-1) and error correction information (e.g., 12 bits of ECC data generated at one or more ECC encoders 216-1-1, . . . , 216-1-X) or false information (e.g., 40 bits generated at the data corruption component 206) whose bit pattern is designed to fail error correction and/or detection operations (e.g., that can be performed at ECC decoders 216-2-1, . . . , 216-2-X and 220 and CRC decoders 213-2 and 215), which can cause the memory controller 204 to report data corruption to the host 102. In some embodiments, the false information can further correspond to (e.g., match) a particular bit pattern assigned as “false information”.

The diagram further shows a memory die 327-5, in which a PDB 339 including RAID parity data can be stored, although embodiments are not limited to a particular quantity of memory dice over which a PDB can be stored. For example, while a first portion of the memory die 327-1-5 can store a PDB, a second portion of the memory die 327-2-5 can store a portion of the supplemental data that are stored over respective second portions of memory dice 327-1, . . . , 327-5.

The memory dice 327-1, . . . , 327-5 can correspond to a data protection channel, such as a RAID (e.g., locked-RAID) channel 329; therefore, the RAID channel 329 can be 5*Y-bit wide (e.g., configured to provide 5*Y bits, such as 40 bits, via DQ pins). Data stored in the memory dice 327-1, . . . , 327-5 can also be a data transfer unit between the memory device (e.g., the memory device 126 and/or 226 illustrated in FIGS. 1 and 2) and the memory controller (e.g., the memory controller 104 and/or 204 illustrated in FIGS. 1 and 2). For example, data corresponding to the cache line 332, supplemental data, and an PDB 339 can be transferred together in response to a host read command to access the data corresponding to the cache line 332. Although not specifically illustrated in FIG. 3, the memory system (e.g., the memory system 101) can include a number of RAID channels, such as four RAID channels (e.g., each corresponding to the RAID channel 329), for example.

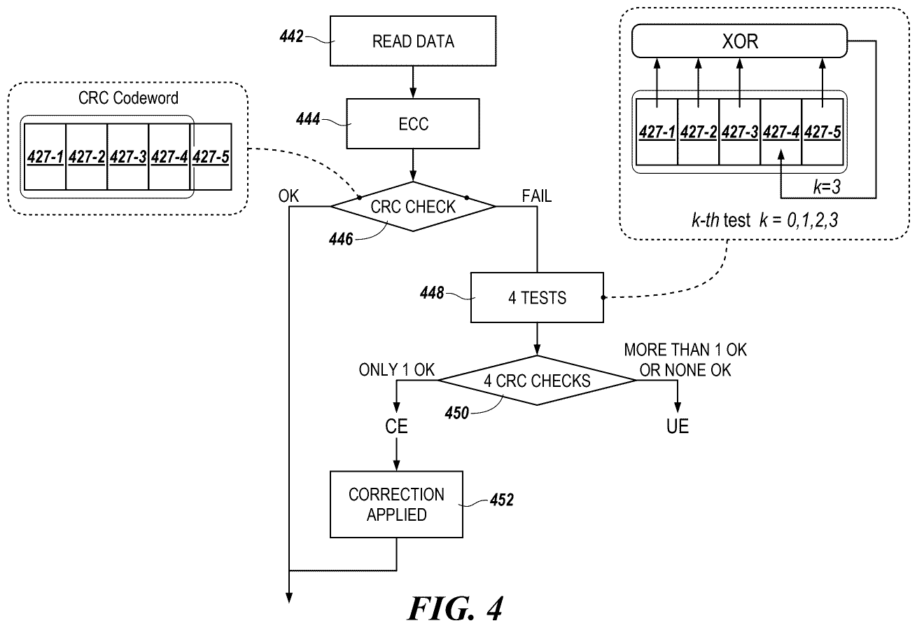

FIG. 4 a locked-RAID process for a data protection channel in accordance with a number of embodiments of the present disclosure. Five memory dice 427-1, . . . , 427-5 illustrated in FIG. 4 can be analogous to memory dice 327-1, . . . , 327-5. For example, five memory dice 427-1, . . . , 427-5 can correspond to a RAID channel with four memory dice 427-1, . . . , 427-4 in which user data (e.g., one or more UDBs) are stored and one memory die 427-5 in which RAID parity data (e.g., a PDB) are stored.

At 442, data can be read from memory devices, such as memory devices 126, 226 illustrated in FIGS. 1 and 2, respectively. Data read from the memory devices can include data (e.g., user data, such as one or more UDBs) corresponding to a cache line, RAID parity data (e.g., an PDB), as well as the other data, such as supplemental data that includes either error correction information (generated at the ECC encoders 216-1-1, . . . , 216-1-X illustrated in FIG. 2) and error detection information (generated at the CRC encoder 213 illustrated in FIG. 2) or false information (generated at the data corruption component 106, 206 illustrated in FIGS. 1 and 2).

At 444, an error correction operation can be performed (e.g., at the ECC decoders 216-2-1, . . . , 216-2-X illustrated in FIG. 2) on the data (e.g., read from the memory dice 427-1, . . . , 427-5) using error correction information (e.g., ECC data) to correct one or more bit errors on the data, if any. If the error correction operation is performed using false information, the error correction operation can result in a failure such that the data are input to the CRC decoder 213-2 illustrated in FIG. 2 without any bit errors being corrected.

At 446, an error detection operation can be performed (e.g., at the CRC decoder 213-2 illustrated in FIG. 2) on the user data (e.g., read from the memory dice 427-1, . . . , 427-4) using error detection information (e.g., CRC data) to detect any bit errors on the user data. If the error correction operation is performed using false information, the error detection operation can result in an indication of one or more bit errors within the user data regardless of whether the user data includes bit errors.

If the error detection information does not indicate (e.g., “OK” as shown in FIG. 4) any bit errors on the user data, a RAID process may not be triggered and the user data can be further processed (e.g., transferred to the other components of the memory controller 204, such as the security decoder 217-2 and/or authentication decoders 218-2 illustrated in FIG. 2). On the other hand, if the error detection information indicates any bit errors (e.g., “FAIL” as shown in FIG. 4), a RAID process can be triggered at 448, in which multiple separate RAID operations can be performed on each portion of the user data corresponding to a respective memory die. In the example illustrated in FIG. 4, four separate RAID operations can be respectively performed on four portions of the user data that respectively correspond to four memory dice.

In further details, a first RAID operation can be performed on user data read from memory dice 427-1 using user data read from memory dice 427-2, . . . , 427-4 and RAID parity data read from the memory die 427-5, a second RAID operation performed can be on user data read from memory dice 427-2 using user data read from memory dice 427-1, 427-3, and 427-4 and RAID parity data read from the memory die 427-5, a third RAID operation can be performed on user data read from memory dice 427-3 using user data read from memory dice 427-1, 427-2, and 427-4 and RAID parity data read from the memory die 427-5, and a fourth RAID operation can be performed on user data read from memory dice 427-4 using user data read from memory dice 427-1, 427-2, and 427-3 and RAID parity data read from the memory die 427-5. In some embodiments, these RAID operations can be performed in parallel. As illustrated in FIG. 4, for example, one of the RAID operations can be performed to recover user data read from memory die 427-4 by comparing (e.g., XORing) user data read from memory dice 427-1, 427-2, 427-3 and RAID parity data 427-5.

At 450, error detection operations (e.g., CRC checks) are performed (e.g., at the CRC decoder 215 illustrated in FIG. 2) on results of the RAID operations to determine if any one of results of the RAID operations does not include any bit errors. In the example illustrated in FIG. 4, four error detection operations can be performed respectively on four results of the four RAID operations performed at 448. If there is a single one of the results being indicated as not having any bit errors, the result can be further input to a next step 452. If none of the results are indicated as not having any bit errors or there is more than one result being indicated as not having any bit errors, the host (e.g., the host 102 illustrated in FIG. 1) can be notified of the corruption on the user data (e.g., read from the memory dice 427-1, . . . , 427-4). If the error correction operations are performed using false information, the error detection operations performed at 450 can be led to indication of one or more bit errors on at least more than one result of the results of the RAID operations performed at 448. At 452, the result (e.g., corresponding to one of the results that is indicated as not having bit errors at 450) selected as a result of the error detection operations performed at 450 can be provided to the other components of the memory controller 204, such as the security decoder 217-2 and/or authentication decoders 218-2 illustrated in FIG. 2.

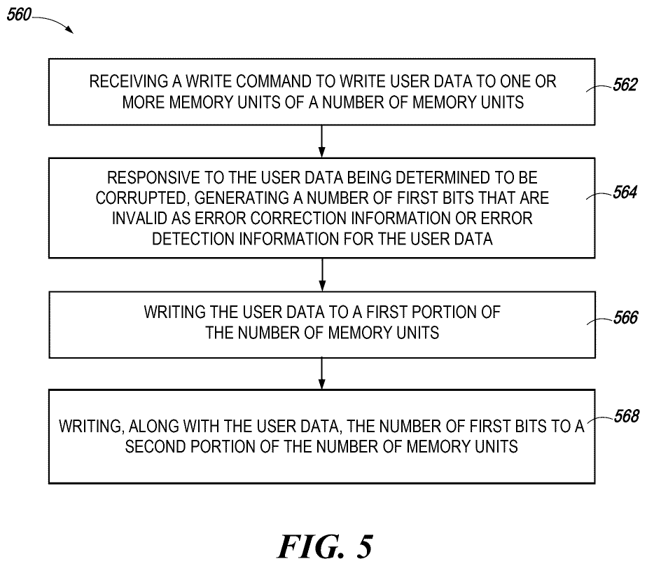

FIG. 5 is a flow diagram of a method 560 for indicating data corruption in accordance with a number of embodiments of the present disclosure. The method 560 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 560 is performed by the memory controller 104 and/or 204 illustrated in FIGS. 1 and 2, respectively. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 562, a write command to write a user data (e.g., one or more UDBs corresponding to a cache line) to one or more memory units of a number of memory units (e.g., memory dice 327 illustrated in FIG. 3) can be received. In some embodiments, first error detection information can be generated (e.g., at the CRC encoder 211-1-1 illustrated in FIG. 2) based on the user data responsive to receiving the write command including the user data. In this example, an error detection operation can be performed (e.g., at the CRC decoder 211-1-2 illustrated in FIG. 2) on the user data using the first error detection information prior to writing the user data to the first portion of the number of memory units and to indicate whether the user data is corrupted or not.

At 564, a number of first bits that are invalid as error correction information (e.g., ECC data) or error detection information (e.g., CRC data) for the user data can be generated (e.g., at the data corruption component 106, 206 illustrated in FIGS. 1 and 2, respectively) responsive to the user data being determined to be corrupted. In some embodiments, the number of first bits can be generated (regardless of whether the user data is determined to have one or more bit errors as a result of the error detection operation performed using the first error detection information) responsive to receiving a request (e.g., from the host 102 illustrated in FIG. 1) to mark the user data as being corrupted.

At 566, the user data can be written to a first portion (e.g., 327-1-1, 327-1-4 illustrated in FIG. 3) of the number of memory units. At 568, the number of first bits (instead of a number of second bits corresponding to the error correction information or the error detection information) can be written to a second portion (e.g., 327-2-1, . . . , 327-2-5 illustrated in FIG. 3) of the number of memory units along with the user data. Alternatively, the number of second bits can be generated (e.g., at the CRC encoder 213-1 and/or ECC encoders 216-1-1, . . . , 216-1-X illustrated in FIG. 2) based on the user data responsive to the user data being determined to be not corrupted. In this example, the number of second bits (instead of the number of first bits) can be written to the second portion of the number of memory units along with the user data.

In some embodiments, the user data and the number of first bits can be read respectively from the first and second portions of the number of memory units. Further, an error correction operation can be performed (e.g., at the ECC encoders 216-1-1, . . . , 216-1-X illustrated in FIG. 2) using the number of first bits on the user data. The error correction operation performed using the number of first bits can result in one or more uncorrectable bit errors on the user data. Further, an error detection operation can be performed (e.g., at the CRC encoder 213-1 illustrated in FIG. 2) using the number of first bits on the user data. The error detection operation performed using the number of first bits results in indication of one or more bit errors in the user data. The user data can be reported as being corrupted responsive to the indication as well as responsive to a bit pattern of the number of first bits corresponding to a particular bit pattern assigned to the corruption (e.g., false information).

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
receiving a write command to write user data to one or more memory units of a number of memory units;
responsive to the user data being determined to be corrupted, generating a number of first bits that are invalid as error correction information or error detection information for the user data;
writing the user data to a first portion of the number of memory units; and
writing, along with the user data, the number of first bits to a second portion of the number of memory units.

2. The method of claim 1, further comprising:
responsive to receiving the write command including the user data, generating first error detection information based on the user data; and
performing an error detection operation on the user data using the first error detection information prior to writing the user data to the first portion of the number of memory units and to indicate whether the user data is corrupted or not.

3. The method of claim 2, further comprising:
responsive to receiving a request to mark the user data as being corrupted, generating the number of first bits regardless of whether the user data is determined to have one or more bit errors as a result of the error detection operation performed using the first error detection information;
writing the user data to the first portion of the number of memory units; and
writing, along with the user data and instead of a number of second bits corresponding to the error correction information or the error detection information, the number of first bits to the second portion of the number of memory units.

4. The method of claim 3, further comprising:
responsive to the user data being determined to be not corrupted, generating the number of second bits based on the user data;
writing the user data to the first portion of the number of memory units; and
writing, along with the user data, the number of second bits to the second portion of the number of memory units.

5. The method of claim 1, further comprising:
reading the user data and the number of first bits respectively from the first and second portions of the number of memory units;
performing an error correction operation using the number of first bits on the user data, wherein the error correction operation performed using the number of first bits results in one or more uncorrectable bit errors on the user data;
performing an error detection operation using the number of first bits on the user data, wherein the error detection operation performed using the number of first bits results in indication of one or more bit errors in the user data; and
responsive to the indication, reporting the user data as being corrupted.

6. The method of claim 5, further comprising:
reporting the user data as being corrupted responsive to the indication and a bit pattern of the number of first bits corresponding to a particular bit pattern assigned to the corruption.

7. An apparatus, comprising:
a plurality of memory units; and
a controller communicatively coupled to the plurality of memory units, the controller configured to:
receive a write command to write user data comprising a number of first bits to a first portion of the plurality of memory units;
responsive to the user data being determined to be corrupted, generate a number of second bits that are invalid as error correction information or first error detection information for the user data such that an error correction operation or an error detection operation performed using the number of second bits on the user data is designed to result in one or more uncorrectable bit errors on the user data or indication of one or more bit errors on the user data; and
write the number of second bits to a second portion of the plurality of memory units instead of a number of third bits corresponding to the error correction information or the first error detection information.

8. The apparatus of claim 7, wherein the controller is configured to write the number of second bits to the second portion of the plurality of memory units via one or more data mask inversion (DMI) pins.

9. The apparatus of claim 7, wherein the controller is further configured to:
in response to the user data being determined to be not corrupted, generate the number of third bits; and
write, instead of the number of second bits, the number of third bits to the second portion of the plurality of memory units.

10. The apparatus of claim 7, wherein the controller is further configured to write, instead of the number of first bits of the user data, the number of second bits to the first portion of the plurality of memory units.

11. The apparatus of claim 7, wherein the number of second bits corresponds to a number of predefined bit patterns.

12. The apparatus of claim 7, wherein the first error detection information corresponds to cyclic redundancy check (CRC) data.

13. The apparatus of claim 7, wherein the controller is further configured to:
generate, prior to the number of second bits or the number of third bits being generated, second error detection information based on the user data in response to receipt of the write command and the user data; and
perform an error detection operation on the user data using the second error detection information to determine whether the user data has one or more bit errors.

14. The apparatus of claim 13, wherein the controller is configured to:
generate the number of second bits in response to the error detection operation performed using the second error detection information indicating one or more bit errors on the user data; and
generate the number of third bits in response to the error detection operation performed using the second error detection information not indicating one or more bit errors on the user data.

15. The apparatus of claim 13, wherein the second error detection information corresponds to cyclic redundancy check (CRC) data.

16. An apparatus, comprising:
a plurality of memory units; and
a controller communicatively coupled to the plurality of memory units, the controller configured to:
receive a write command to write user data to at least a portion of the plurality of memory units;
responsive to the user data being determined to be not corrupted, generate a number of first bits corresponding to error correction information or first error detection information generated based on the user data;
responsive to the user data being determined to be corrupted, generate a number of second bits not corresponding to the error correction information or the first error detection information, wherein a respective bit pattern of the error correction information or error detection information is designed to cause:
an error correction operation performed using the number of second bits on the user data to result in one or more uncorrectable bit errors; and
an error detection operation performed using the number of second bits on the user data to result in indication of one or more bit errors on the user data.
write the user data to a first portion of the plurality of memory units; and
write, along with the user data, the number of first or second bits to a second portion of the plurality of memory units.

17. The apparatus of claim 16, wherein the controller is configured to:
read the user data and the number of first bits respectively from the first and second portions of the plurality of memory units;
perform the error correction operation or the error detection operation on the user data using the number of second bits; and
responsive to the error correction operation or the error detection operation having been failed, report the user data as being corrupted.

18. The apparatus of claim 16, wherein the controller is configured to:
generate second error detection information based on the user data in response to receipt of the write command; and
perform, prior to the user data being written to the first portion of the plurality of memory units, an error detection operation on the user data using the second error detection information to determine whether the user data has one or more bit errors.

19. The apparatus of claim 18, wherein the controller is configured to write, instead of the number of second bits, the number of first bits to the second portion of the plurality of memory units in response to the user data being determined to have the one or more bit errors.

20. The apparatus of claim 18, wherein the controller is configured to write, instead of the number of first bits, the number of second bits to the second portion of the plurality of memory units in response to the user data being determined not to have the one or more bit errors.
